(19) United States
(12) Patent Application Publication
(10) Pub. No.: US 2019/0035651 A1
(43) Pub. Date: Jan. 31, 2019

(54) SUBSTRATE CLEANING METHOD, SUBSTRATE CLEANING DEVICE, AND METHOD OF SELECTING CLUSTER GENERATING GAS

(71) Applicant: TOKYO ELECTRON LIMITED, Tokyo (JP)

(72) Inventor: Kazuya DOBASHI, Yamanashi (JP)

(21) Appl. No.: 16/071,480

(22) PCT Filed: Dec. 8, 2016
(86) PCT No.: PCT/JP2016/086607

§ 371 Date: Jul. 19, 2018

(30) Foreign Application Priority Data
Jan. 21, 2016 (JP) 2016-009532

(51) Int. Cl. H01L 21/67; H01L 21/02; B08B 7/00

(52) U.S. Cl. CPC H01L 21/67051; B08B 7/0071; H01L 21/02041

(57) ABSTRACT

A substrate cleaning method includes injecting a cluster generating gas from a cluster nozzle into a processing chamber, generating gas clusters by adiabatically expanding the cluster generating gas, and removing particles adhered to a target substrate in the processing chamber by irradiating the gas clusters onto the target substrate. The cluster generating gas is selected based on a product Φ of energy K per molecule or atom of the cluster generating gas that is expressed by the following equation (1) and an index C indicating the ease with which the gas forms clusters that is expressed by the following equation (2), K=1/2mv²=γ/γ−1k_{B}T₀ . . . (1) C=(T_{b}/T₀)^{γ/γ-1} . . . (2) where k_{B}: a Boltzmann constant, γ: a specific heat ratio of the cluster generating gas, m: a mass of the cluster generating gas, v: a speed of the cluster generating gas, T₀: a gas supply temperature, T_{b}: a boiling point of the cluster generating gas.

### FIELD OF THE INVENTION

The present invention relates to a substrate cleaning method, a substrate cleaning device, and a method of selecting a cluster generating gas.

### BACKGROUND OF THE INVENTION

In a semiconductor device manufacturing process, particles adhered to a semiconductor substrate lead to defects of a product and, thus, a cleaning process for removing the particles adhered to the substrate is performed. As for a substrate cleaning technique, attention is paid to a technique of irradiating gas clusters on a surface of the substrate and removing particles on the surface of the substrate by physical action thereof.

For example, U.S. Pat. No. 5,062,898 proposes a technique for generating clusters of CO₂ or Ar and making the clusters collide with a substrate to perform physical cleaning. Recently, however, it is required to remove fine particles from submicron to nano-scale. In order to remove the fine particles with high efficiency, a high-speed gas cluster is required. In the case of using CO₂ or Ar alone, it is difficult to obtain gas clusters of a desired speed.

On the other hand, Japanese Patent Application Publication No. 2014-72383 discloses a technique for accelerating a cluster generating gas by mixing an accelerating gas such as He or the like with a cluster generating gas such as CO₂ or the like as a method of cleaning a surface of a substrate by using gas clusters. However, such a technique is disadvantageous in that a supply pressure and a flow rate of a gas need to be increased and also disadvantageous in that an apparatus becomes complicated and scaled up due to a requested booster or the like.

On the other hand, U.S. Pat. No. 6,449,873 discloses a technique of generating large-sized gas clusters or aerosol at a low supply pressure by cooling a gas line for supplying a cluster generating gas to an extremely low temperature of 100K or less. However, a speed of the generated gas clusters or aerosol is low, and it is difficult to remove fine removal targets with high efficiency. In the case of using large-sized clusters, it is difficult to remove particles in a fine pattern and the fine pattern may be damaged.

### SUMMARY OF THE INVENTION

In view of the above, the present invention provides a substrate cleaning method and a substrate cleaning apparatus capable of removing fine particles with nigh efficiency by gas clusters without using a complicated and scaled-up apparatus.

The present invention also provides a method of selecting a cluster generating gas capable of cleaning a substrate.

In accordance with a first aspect of the present invention, there is provided a substrate cleaning method including: supplying a cluster generating gas to a cluster nozzle at a predetermined pressure; injecting the cluster generating gas from the cluster nozzle into a processing chamber accommodating a target substrate and maintained in a vacuum state; generating gas clusters by adiabatically expanding the cluster generating gas; and removing particles adhered to the target substrate by irradiating the gas clusters onto the target substrate in the processing chamber, wherein the cluster generating gas is selected based on a product Φ of energy K per molecule or atom of the cluster generating gas injected from the cluster nozzle that is expressed by the following equation (1) and an index C indicating the ease with which the gas forms clusters that is expressed by the following equation (2),

$$K = \frac{1}{2} {mv}^{2} = \frac{γ}{γ - 1} {k}_{B} {T}_{0} \qquad ( 1 )$$

where k_{B} represents a Boltzmann constant; γ represents a specific heat ratio of the cluster generating gas; m represents a mass of the cluster generating gas; v represents a speed of the cluster generating gas; and T₀ represents a gas supply temperature,

$$C = {( \frac{{T}_{b}}{{T}_{0}} )}^{\frac{γ}{γ - 1}} \qquad ( 2 )$$

where T_{b} represents a boiling point of the cluster generating gas, T₀ represents a gas supply temperature and γ represents a specific heat ratio of the cluster generating gas.

In accordance with a second aspect of the present invention, there is provided a substrate cleaning apparatus for cleaning a substrate by using gas clusters, including: a processing chamber accommodating a target substrate and maintained in a vacuum state; a substrate holding unit configured to hole the target substrate in the processing chamber; a gas exhaust unit configured to exhaust the processing chamber; a cluster generating gas supply unit configured to supply a cluster generating gas; and a cluster nozzle configured to inject the cluster generating gas supplied from the cluster generating gas supply unit at a predetermined pressure into the processing chamber and irradiate gas clusters generated by adiabatic expansion of the cluster generating gas onto the target substrate, wherein the cluster gas supply unit uses as the cluster generating gas a gas selected based on a product Φ of energy K per molecule or atom of the cluster generating gas injected from the cluster nozzle that is expressed by the following equation (1) and an index C indicating the ease with which the gas forms clusters that is expressed by the following equation (2),

$$K = \frac{1}{2} {mv}^{2} = \frac{γ}{γ - 1} {k}_{B} {T}_{0} \qquad ( 1 )$$

where k_{B} represents a Boltzmann constant; γ represents a specific heat ratio of the cluster generating gas; m represents a mass of the cluster generating gas; v represents a speed of the cluster generating gas; and T₀ represents a gas supply temperature,

$$C = {( \frac{{T}_{b}}{{T}_{0}} )}^{\frac{γ}{γ - 1}} \qquad ( 2 )$$

where T_{b} represents a boiling point of the cluster generating gas, T₀ represents a gas supply temperature and γ represents a specific heat ratio of the cluster generating gas.

In accordance with a third aspect of the present invention, there is provided a method of selecting a cluster generating gas in supplying a cluster generating gas to a cluster nozzle at a predetermined pressure, injecting the cluster generating gas from the cluster nozzle into a processing chamber accommodating a target substrate and maintained in a vacuum state, and removing particles of the target object by irradiating gas clusters generated by adiabatic expansion of the cluster generating gas onto the target substrate, wherein the cluster generating gas is selected based on a product Φ of energy K per molecule or atom of the cluster generating gas injected from the cluster nozzle that is expressed by the following equation (1) and an index C indicating the ease with which the gas forms clusters that is expressed by the following equation (2),

$$K = \frac{1}{2} {mv}^{2} = \frac{γ}{γ - 1} {k}_{B} {T}_{0} \qquad ( 1 )$$

where k_{B} represents a Boltzmann constant; γ represents a specific heat ratio of the cluster generating gas; m represents a mass of the cluster generating gas; v represents a speed of the cluster generating gas; and T₀ represents a gas supply temperature, and

$$C = {( \frac{{T}_{b}}{{T}_{0}} )}^{\frac{γ}{γ - 1}} \qquad ( 2 )$$

where T_{b} represents a boiling point of the cluster generating gas; T₀ represents a gas supply temperature; and γ represents a specific neat ratio of the cluster generating gas.

In the first to the third aspect, a gas having a value of Φ greater than a value of Φ of CO₂ gas may be used as the cluster generating gas.

In the first and the second aspect, a supply temperature of the cluster generating gas may be 220K or more. Further, the cluster generating gas may be any one of C₃H₆, C₃H₈, and C₄H₁₀.

An accelerating gas for accelerating the gas cluster may be mixed with the cluster generating gas and the mixed gas may be supplied to the cluster nozzle. The accelerating gas may be H₂ or He.

A size of the gas cluster may be controlled by a supply pressure of the cluster generating gas or the mixed gas, a supply temperature of the cluster generating gas or the mixed gas, or an orifice diameter of the cluster nozzle.

In accordance with the present invention, the gas type of the cluster generating gas is selected based on the product Φ of the energy K per molecule or atom of the cluster generating gas injected from the cluster nozzle and the index C indicating the ease with which the gas forms clusters. Therefore, it is possible to select a gas that generates gas clusters with an extremely high total energy and also possible to remove fine particles with high efficiency by the gas clusters of the selected gas. By selecting such a gas, it is possible to reduce the gas supply pressure, the gas flow rate, and the like and also possible to prevent the apparatus from being complicated and scaled-up.

### BRIEF DESCRIPTION OF THE DRAWINGS

FIG. 1 is a cross sectional view showing a substrate cleaning apparatus according to an embodiment.

FIG. 2 shows an index value C indicating the ease with which the gas forms clusters, an energy K per molecule (atom), and a product Φ of the index value C and the energy K of each gas at a gas temperature of 27° C. (300K).

FIG. 3 snows relation between a supply temperature T₀ of each gas and the product Φ of the energy K per molecule and the index value C indicating the ease with which the gas forms clusters in the case of inert gases.

FIG. 4 shows relation between a supply temperature T₀ of each gas and the product Φ of the energy K per molecule and the index value C indicating the ease with which the gas forms clusters in the case of corrosive gases or liquid at a room temperature.

FIG. 5 shows relation between a supply temperature T₀ of each gas and the product Φ of the energy K per molecule and the index value C indicating the ease with which the gas forms clusters in the case of combustible gases or the like.

FIG. 6 is a cross sectional view showing a substrate cleaning apparatus according to another embodiment.

### DETAILED DESCRIPTION OF THE EMBODIMENTS

The inventor of the present invention has repeatedly studied to obtain gas clusters capable of removing fine particles with high efficiency without using a complicated and scaled-up apparatus. As a result, the present inventor has found that as particles to be removed become smaller, a total energy (=the number of collision molecules×the energy per molecule) of molecules of clusters that collide with the particles needs to be higher to obtain high particle removal performance, and this is particularly remarkable at the time of removing particles inside a pattern having a narrow space width. As a result of further investigation, it has been found that it is effective to select a gas type of a cluster generating gas based on a product of the energy per molecule or atom of the cluster generating gas injected from a cluster nozzle and an index indicating the ease with which the gas forms clusters which is calculated from a boiling point, a specific heat ratio and a temperature of the gas. The present invention has been conceived based on these findings.

Hereinafter, embodiments will be described with reference to the accompanying drawings.

<Substrate Cleaning Apparatus>

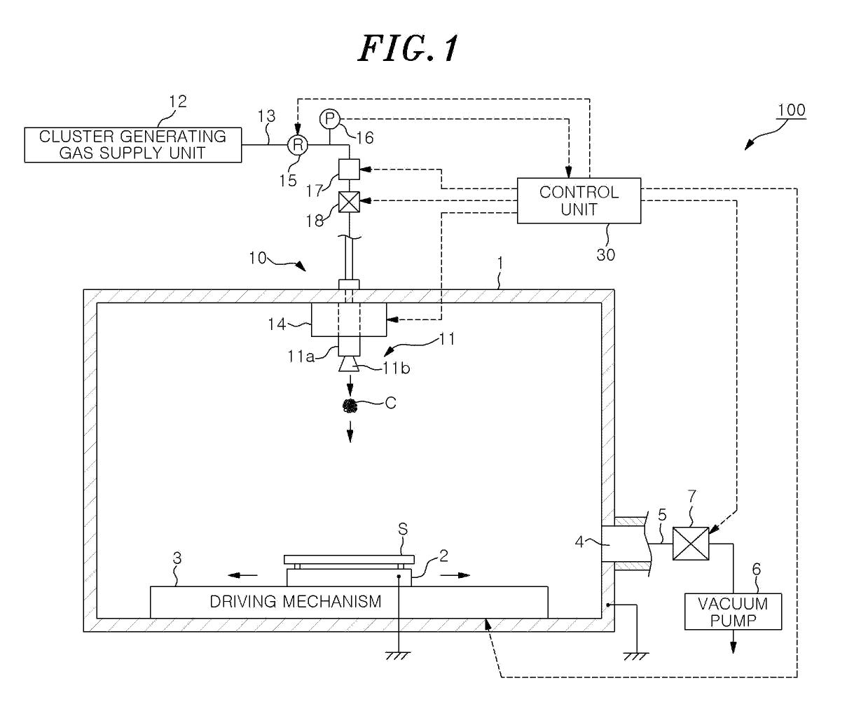

FIG. 1 is a cross sectional view showing a substrate cleaning apparatus according to an embodiment of the present invention. A substrate cleaning apparatus 100 performs a process of cleaning a substrate by removing particles adhered to the substrate by gas clusters.

The substrate cleaning apparatus 100 includes a processing chamber 1 for defining a processing space for performing a cleaning process. A substrate mounting table 2 for mounting thereon a target substrate S is provided in the processing chamber 1. As for the target substrate S, various substrates such as a semiconductor wafer, a glass substrate for a flat panel display and the like may be used as long as particles adhered thereto need to be removed. The substrate mounting table 2 is driven by a driving mechanism 3.

A gas exhaust port 4 is provided at a lower portion of a sidewall of the processing chamber. A gas exhaust line 5 is connected to the gas exhaust port 4. A vacuum pump 6 is provided in the gas exhaust line 5, and the processing chamber 1 is evacuated by the vacuum pump 6. A degree of vacuum at this time can be controlled by a pressure control valve 7 provided in the gas exhaust line 5. These components constitute a gas exhaust unit, and the processing chamber 1 is maintained at a predetermined vacuum level.

A gas cluster irradiation mechanism 10 for irradiating a cleaning gas cluster onto the target substrate S is provided above the substrate mounting table 2. The gas cluster irradiation mechanism 10 includes: a cluster nozzle 11 provided at an upper portion in the processing chamber 1 to face the substrate mounting table 2; a cluster generating gas supply unit 12, provided outside the processing chamber 1, for supplying a gas for generating clusters to the cluster nozzle 11; a gas supply line 13 for guiding a gas from the cluster generating gas supply unit 12 to the cluster nozzle 11; and a temperature control unit 14 for controlling a temperature of gas clusters. The gas supply line 13 is provided with a pressure controller 15, a pressure gauge 16, a flow rate controller 17 and an opening/closing valve 18 from an upstream side. The cluster nozzle 11 has a cylindrical pressure tube 11a and a conical injection port 11b which is provided at a leading end of the pressure tube 11a and gradually widened. An orifice is formed between the pressure tube 11a and the injection port 11b. The shape of the injection port 11b is not limited to the conical shape.

When the cluster generating gas is supplied from the cluster generating gas supply unit 12, a flow rate thereof is controlled by the flow rate controller 17 and a supply pressure thereof is controlled to a pressure of, e.g., about 0.1 to 5.0 Mpa, by the pressure controller 15 based on a pressure measured by the pressure gauge 16 provided in the gas supply line 13. The cluster generating gas introduced into the gas cluster nozzle 11 from the gas supply line 13 exists as molecules or atoms. However, the cluster generating gas that has reached the injection port 11b from the high-pressure pressure tube 11a through the orifice is cooled to a temperature lower than a condensation temperature by rapid adiabatic expansion because a pressure therein is the same as the vacuum pressure in the processing chamber 1. Thus, about 10⁷ molecules or atoms are aggregated by van der Waals force and become gas clusters C. Then, the generated gas clusters C are injected through the injection port 11b into the processing chamber 1, and fine particles adhered to the target substrate S are removed by the gas clusters C irradiated onto the target substrate S.

As will be described later, the cluster generating gas is selected based on a product of energy per molecule or atom of the cluster generating gas injected from the cluster nozzle 11 and an index indicating the ease with which the gas forms clusters that is calculated from a boiling point, a specific heat ratio and a temperature of the gas.

In order to distribute the generated gas clusters onto the target substrate S without destroying them, it is preferable to set a pressure in the processing chamber 1 to a low level. For example, the pressure in the processing chamber 1 is preferably 300 Pa or less when a supply pressure of a gas supplied to the cluster nozzle 11 is 1 MPa or less, and 600 Pa or less when the supply pressure of the gas supplied to the cluster nozzle 11 is within a range from 1 MPa to 5 MPa.

The above-described driving mechanism 3 moves the substrate mounting table 2 in a plane so that the gas cluster C injected from the cluster nozzle 11 is irradiated to the entire surface of the target substrate S. The driving mechanism 3 is, e.g., an XY table. Instead of moving the target substrate S by the driving mechanism 3 through the substrate mounting table 2, the cluster nozzle 11 may be moved in a plane, or both of the substrate mounting table 2 and the cluster nozzle 11 may be moved in a plane. The substrate mounting table 2 may be rotated and the cluster nozzle may be relatively moved. Alternatively, the substrate mounting table 2 may be rotated and moved in parallel to the cluster nozzle.

A loading/unloading port (not shown) for loading/unloading the target substrate S is provided on a sidewall of the processing chamber 1. The processing chamber 1 is connected to a vacuum transfer chamber (not shown) through the loading/unloading port. The loading/unloading port can be opened and closed by a gate valve (not shown), and the target substrate S is loaded into and unloaded from the processing chamber 1 by a substrate transfer unit in the vacuum transfer chamber.

The substrate cleaning apparatus 100 includes a control unit 30. The control unit 30 includes a controller having a microprocessor which controls gas supply of the substrate cleaning apparatus 100 (the pressure controller 15, the flow rate controller 17, and the opening/closing valve 18), evacuation of gas (the pressure control valve 7), driving of the substrate mounting table 2 by the driving mechanism 3, and the like. The controller is connected to a keyboard through which an operator inputs commands to manage the substrate cleaning apparatus 100, a display for visualizing and displaying an operation status of the substrate cleaning apparatus 100, and the like. The controller is connected to a steerage unit that stores a processing recipe that is a control program for controlling each component of the substrate cleaning apparatus 100 to execute a predetermined process based on a control program for realizing a process in the substrate cleaning apparatus 100 under the control of the controller, various database, and the like. The recipe is stored in an appropriate storage medium in the storage unit. If necessary, a desired recipe is read-out from the storage unit and executed by the controller. Accordingly, a desired process is performed in the substrate cleaning apparatus 100 under the control of the controller.

In the substrate cleaning apparatus 100 configured as described above, first, the gate valve is opened, the target substrate S is loaded through the loading/unloading port and mounted on the substrate mounting table 2. Next, the processing chamber 1 is evacuated by the vacuum pump 6 to a predetermined vacuum level. At the same time, the cluster generating gas is supplied at a predetermined flow rate from the cluster generating gas supply unit 12 and is injected from the cluster nozzle 11 at a predetermined supply pressure. Since a pressure in the pressure tube 11a of the cluster nozzle 11 is high, the cluster generating gas exists as molecules or atoms. However, the cluster generating gas that has reached the injection port 11b through the orifice is cooled to a temperature lower than a condensation temperature by rapid adiabatic expansion because a pressure therein is the same as the vacuum pressure in the processing chamber 1. Thus, parts of the molecules or the atoms are aggregated by van der Waals force and become gas clusters C. Then, the generated gas clusters C are injected through the injection port 11b into the processing chamber 1, and fine particles adhered to the target substrate S are removed by the gas clusters C irradiated onto the target substrate S.

<Selection of Cluster Generating Gas>

Next, the selection of the cluster generating gas will be described.

In the present embodiment, the cluster generating gas is selected based on a product of the energy per molecule or atom of the cluster generating gas injected from the cluster nozzle 11 and the index indicating the ease with which the gas forms clusters that is calculated from a boiling point, a specific heat ratio and a temperature of the gas.

Specifically, the gas type of the cluster generating gas is selected based on the product of the energy per molecule or atom of the cluster generating gas injected from the cluster nozzle 11, as expressed by the following equation (1), and the index C indicating the ease with which the gas forms clusters, as expressed by the following equation (2), i.e., Φ=K×C.

$$K = \frac{1}{2} {mv}^{2} = \frac{γ}{γ - 1} {k}_{B} {T}_{0} \qquad ( 1 )$$

Here, k_{B} represents a Boltzmann constant; γ represents a specific heat ratio of the cluster generating gas; m represents a mass of the cluster generating gas; v represents a speed of the cluster generating gas; and T₀ represents a gas supply temperature.

$$C = {( \frac{{T}_{b}}{{T}_{0}} )}^{\frac{γ}{γ - 1}} \qquad ( 2 )$$

Here, T_{b} represents a boiling point of the cluster generating gas; T₀ represents the gas supply temperature; and γ represents the specific heat ratio of the cluster generating gas.

As described above, as the particle to be removed become smaller, the total energy (=the number of collision molecules×the energy per molecule) of the molecules of the gas clusters that collide with the particles needs to be higher to obtain high particle removal performance. This is particularly remarkable in the case of removing particles inside a pattern having a narrow space width. In order to increase the total energy, it is important to increase the energy K per molecule or atom of the cluster generating gas. However, a gas that does not generate clusters is not effective even if the energy per molecule or atom of the gas is high. Therefore, in the present embodiment, the gas type of the cluster generating gas is selected based on the product Φ of the energy K per molecule or atom of the cluster generating gas injected from the cluster nozzle 11 and the index C indicating the ease with which the gas forms clusters.

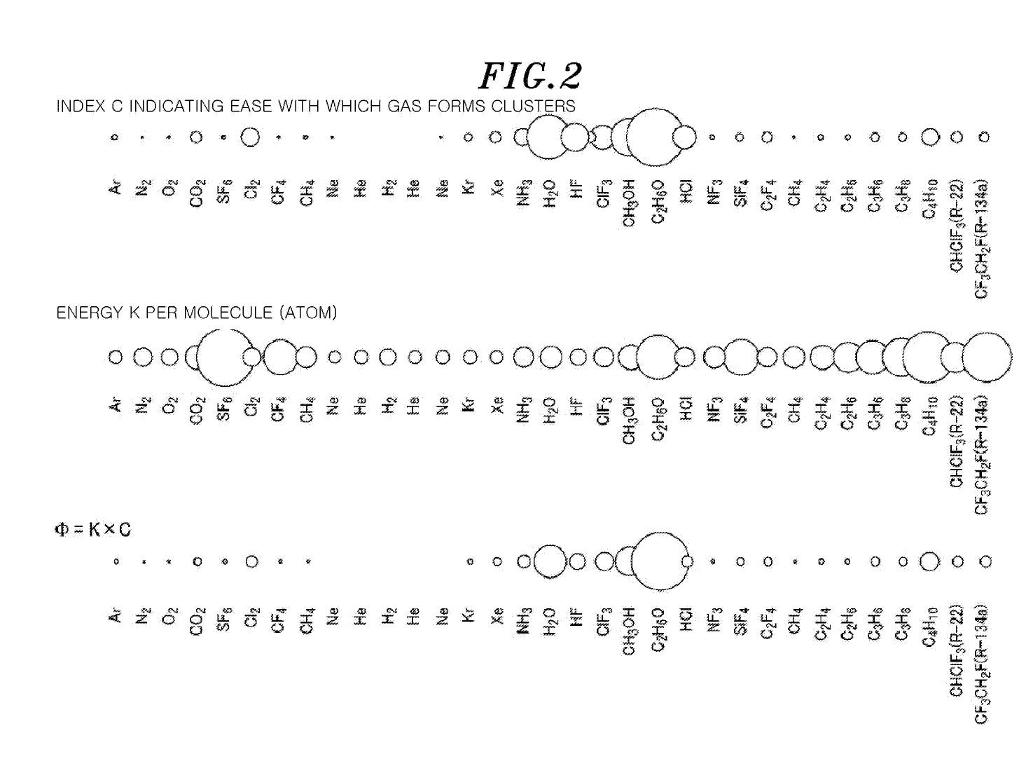

FIG. 2 shows the index C indicating the ease with which the gas forms clusters, the energy K per molecule (atom), and the product Φ of the index C and the energy K of each gas at a gas temperature of 27° C. (300K). In FIG. 2, a circle size of each gas indicates magnitude of each value. For example, the energy per molecule of SF₆ is high as shown in FIG. 2. However, at this temperature, the index C indicating the ease with which the gas forms clusters is small, and it is difficult to generate clusters. Therefore, a gas having a large product Φ of the energy K per molecule and the index C indicating the ease with which the gas forms clusters is effective for a cleaning process using gas clusters.

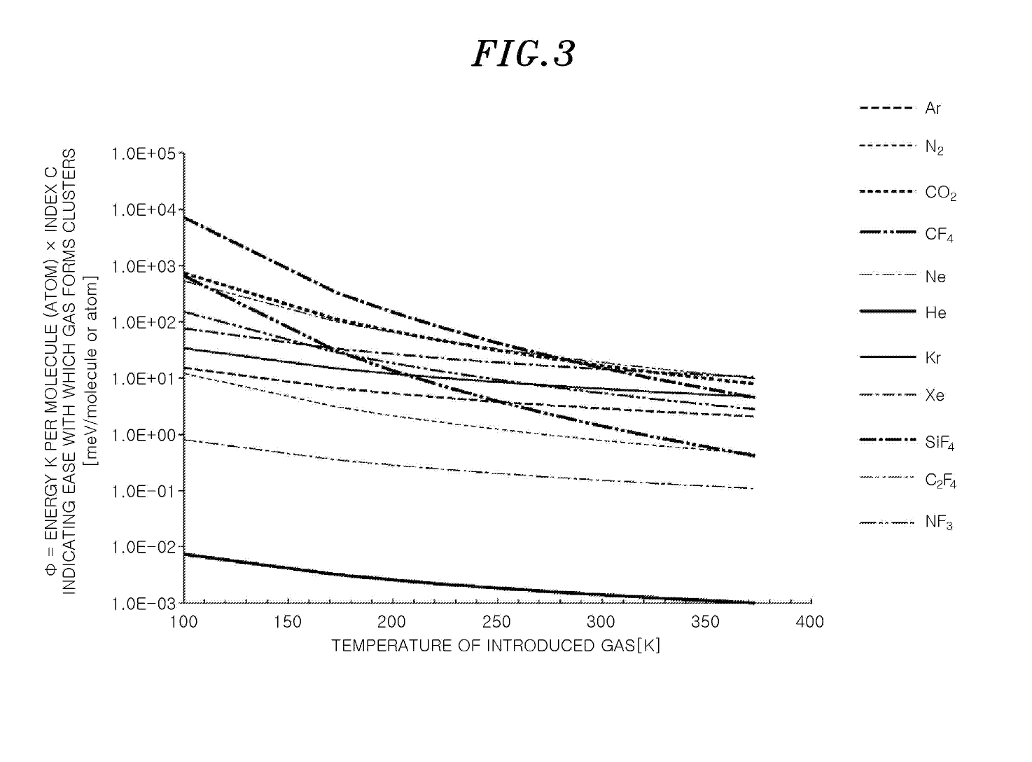

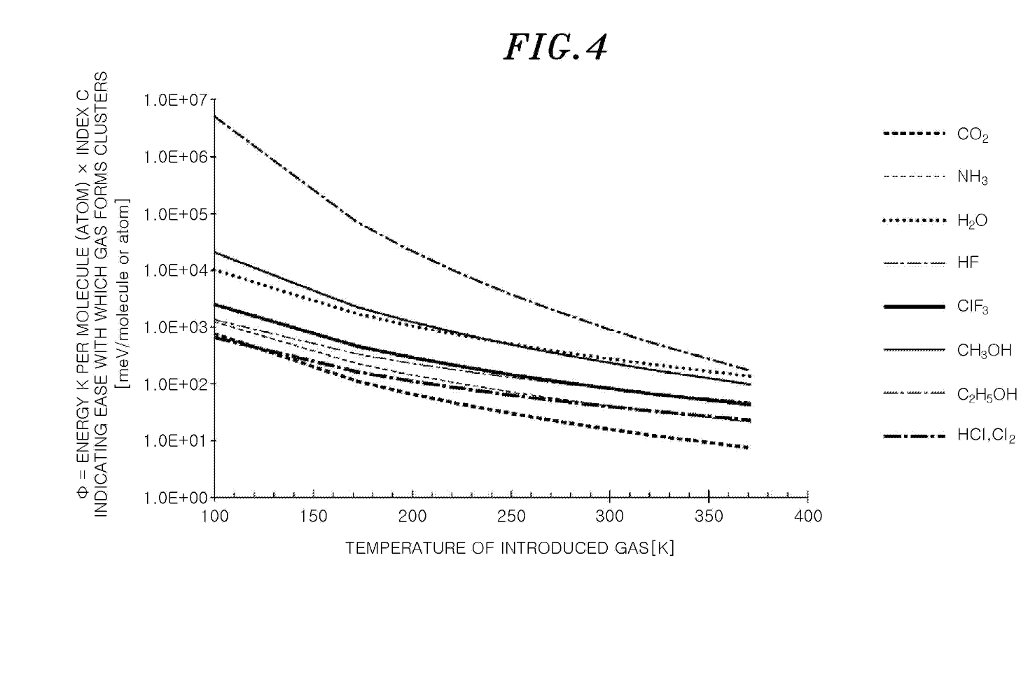

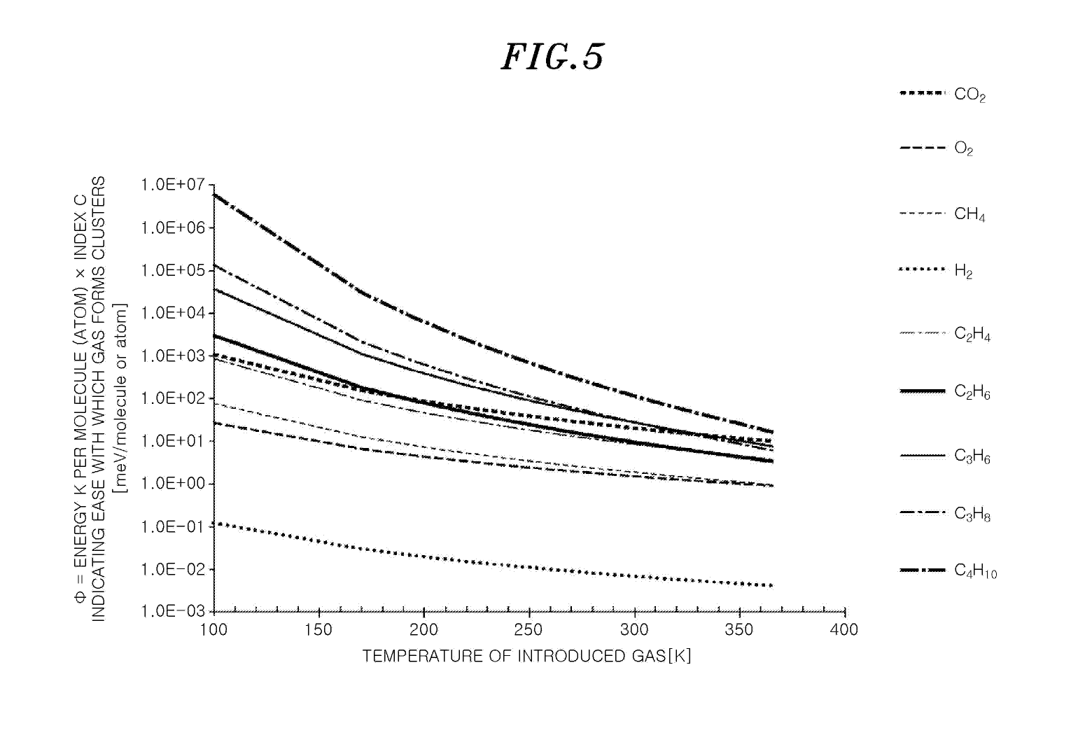

From the fact that the index C indicating the ease with which the gas forms clusters and the energy K per molecule (atom) are the functions of the gas supply temperature (i.e., the temperature of the cluster nozzle) T₀, FIGS. 3 to 5 show the relation between the gas supply temperature T₀ and the product Φ. FIG. 3 shows the relation thereof in the case of inert gases. FIG. 4 shows the relation thereof in the case of corrosive gases or liquid at a room temperature. FIG. 5 shows the relation thereof in the case of combustible gases or the like.

Conventionally, N₂, Ar, and CO₂ are frequently used as the cluster generating gas, and the gas supply temperatures thereof (i.e., the temperature of the cluster nozzle) are extremely low, e.g., about 100K to 220K. Referring to FIG. 3, the value of Φ in this temperature range of N₂, Ar and CO₂ is 1.5 to 740 (meV/molecule or atom). Among them, the value of Φ of CO₂ is largest. From this, it is preferable to select a gas having a value of Φ greater than that of CO₂ as the cluster generating gas. On the other hand, as shown in FIG. 4, the values of Φ of C₂H₅OH, CH₃OH, and H₂O in a liquid state at a normal temperature and the values of Φ of ClF₃, Cl₂, HF, NH₃, and HCl as corrosive gases are greater than that of CO₂. However, it is difficult to stably ensure a gas supply pressure by a gas that is not in a liquid state at a room temperature, and the corrosive gas is not suitable as the cluster generating gas.

Therefore, it is preferable to select C₃H₆ (propylene), C₃H₈ (propane), and C₄H₁₀ (butane) as hydrocarbon (CₓH_{y}) shown in FIG. 5 because they are non-corrosive gases having values of Φ greater than that of CO₂ and allow the gas supply pressure to be ensured stably. They have values of Φ greater than that of CO₂ even at the gas supply temperature of 220K or more and can form clusters at a temperature higher than that in a conventional case. As shown in FIG. 3, Xe, SiF₄, and C₂F₄ among the inert gases have values of Φ greater than that of CO₂ depending on the gas supply temperature. Accordingly, Xe, SiF₄, and C₂F₄ can be selected as the cluster generating gas even though the usage temperature range thereof is limited compared to that of C₃H₆, C₃H₈, and C₄H₁₀.

In the present embodiment, the gas type of the cluster generating gas is selected based on the product Φ of the energy K per molecule or atom of clusters injected from the cluster nozzle 11 and the index C indicating the ease with which the gas forms clusters. Therefore, it is possible to select a gas that generates gas clusters with an extremely high total energy and remove fine particles with high efficiency by the gas clusters of the selected gas. By selecting such a gas, it is possible to reduce the gas supply pressure, the gas flow rate and the like, and also possible to prevent the apparatus from being complicated and scaled-up. Specifically, the above effects can be realized by selecting the gas, e.g., C₃H₆, C₃H₈, and C₄H₁₀, (Xe, SiF₄, and C₂F₄ depending on the usage temperature range) having values of Φ greater than that of conventionally used CO₂, as the cluster generating gas.

When the gas that can easily form clusters and has a large index C indicating the ease with which the gas forms clusters is selected, the size of gas clusters to be generated can be increased. As disclosed in Japanese Patent Application Publication No. H8-127867, the relational expression of the gas cluster size is expressed by the following equation (3).

$$Ψ = {P}_{0} {{D}_{0} ( \frac{{T}_{b}}{{T}_{0}} )}^{γ ( γ - 1 )} \qquad ( 3 )$$

Here, P₀ represents a gas supply pressure; D₀ indicate an orifice diameter of the cluster nozzle; T_{b} represents a boiling point of the cluster generating gas; T₀ represents a gas supply temperature; and γ represents a specific heat ratio of the cluster generating gas.

ψ in the above equation (3) represents a parameter of the gas cluster size. ψ is obtained by multiplying the index C indicating the ease with which the gas forms clusters by the gas supply pressure P₀ and the orifice diameter D₀ of the cluster nozzle. Therefore, in the present embodiment, it is possible to obtain gas clusters having a desired size at a lower supply pressure P₀ by increasing the value of C. Similarly, the flow rate of the gas introduced into the processing chamber 1 can be decreased by reducing the orifice diameter D₀ of the cluster nozzle together with the reduction in the gas supply pressure. Accordingly, it is possible to avoid adverse effects such as deterioration of the energy of the gas cluster due to the collision between the residual gas in the processing chamber 1 and the gas clusters.

<Control of Other Parameters Related to Cluster Generation>

After the cluster generating gas is selected as described above, other parameters related to the cluster generation may be controlled.

(Use of Accelerating Gas)

The gas clusters to be generated can be accelerated by supplying to the cluster nozzle a mixed gas of the cluster generating gas (e.g., C₃H₈) selected based on the product Φ of the energy K per molecule or atom of the cluster generating gas and the index C indicating the ease with which the gas forms clusters and an accelerating gas (e.g., H₂, He or the like) injected from the cluster nozzle and accelerated by adiabatic expansion.

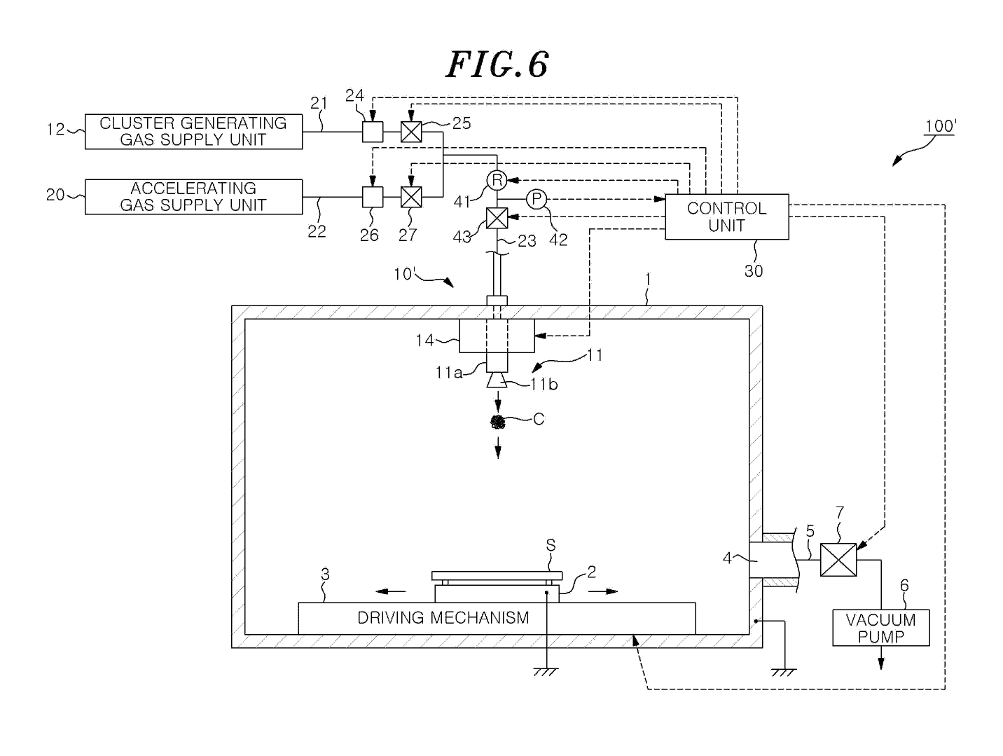

FIG. 6 is a cross sectional view showing a substrate cleaning apparatus using an accelerating gas.

A substrate cleaning apparatus 100′ is different from the substrate cleaning apparatus 100 shown in FIG. 1 in that a gas cluster irradiation mechanism 10′ capable of supplying a mixed gas of a cluster generating gas and an accelerating gas is provided instead of the gas cluster irradiation mechanism 10. The other configurations are the same as those of the substrate cleaning apparatus 100. Like reference numerals will be given to like parts, and redundant description thereof will be omitted.

The gas cluster irradiation mechanism 10′ includes: a cluster nozzle 11 provided at an upper portion of the processing chamber 1 to face the substrate mounting table 2; a cluster generating gas supply unit 12, provided outside the processing chamber 1, for supplying a cluster generating gas to the cluster nozzle 11; an accelerating gas supply unit 20 for supplying an accelerating gas to the cluster nozzle 11; a line system for guiding a mixed gas of the cluster generating gas and the accelerating gas to the cluster nozzle 11; and a temperature control unit 14 for controlling a temperature of the gas clusters. The line system includes: a first line 21 extending from the cluster generating gas supply unit 12; a second line 22 extending from the accelerating gas supply unit 20; and a mixing line 23 where the first and the second line 21 and 22 are joined, for guiding the mixed gas to the cluster nozzle 11. A flow rate controller 24 and an opening/closing valve 25 are provided in the first line 21 from an upstream side. A flow rate controller 26 and an opening/closing valve 27 are provided in the second line 22 from an upstream side. A pressure controller 41, a pressure gauge 42 and an opening/closing valve 43 are provided in the mixing line 23 from an upstream side.

When the cluster generating gas and the accelerating gas are supplied, the flow rates thereof are controlled by the flow rate controllers 24 and 26, and a supply pressure of the mixed gas having a predetermined mixture ratio is controlled to, e.g., about 0.1 MPa to 5 MPa, by the pressure controller 41 based on the pressure measured by the pressure gauge 41 provided in the mixing line 23. In the mixed gas introduced into the gas cluster nozzle 11 from the mixing line 23, the cluster generating gas becomes gas clusters by rapid adiabatic expansion that occurs when the cluster generating gas is supplied into the processing chamber 1 from the high-pressure cluster nozzle 11, and the accelerating gas accelerates the gas clusters without becoming clusters. A flow rate ratio of the accelerating gas to the mixed gas is preferably within a range from 1% to 99%.

By accelerating the gas clusters, the value of K can be increased and the total energy of the gas clusters can be increased. Accordingly, the cleaning performance can be further enhanced. However, in the present embodiment, the demand for the accelerating gas is lower than that in the conventional case, because the cluster gas that easily forms clusters compared to conventionally used CO₂ and has high energy per molecule is selected based on the product Φ of the energy K per molecule or atom of the cluster generating gas and the index C indicating the ease with which the gas forms clusters. In other words, even if the demand for the accelerating gas is lower than that in the conventional case, it is possible to generate gas clusters having high cleaning performance.

(Control of Gas Cluster Size)

The gas cluster size can be controlled by the supply pressure of the cluster generating gas or the mixed gas, the temperature of the cluster nozzle (or injected gas), or the orifice diameter of the cluster nozzle.

For example, when the supply pressure of the cluster generating gas is low (when the gas supply pressure is lowered under the condition that the ratio of the accelerating gas is high and the ratio of the cluster generating gas is low), the size of the gas clusters to be generated may become considerably small. In that case, it is effective to increase the size of the gas cluster by lowering the gas supply temperature (=the temperature of the cluster nozzle) or by increasing the orifice diameter.

However, when the size of the gas cluster is increased by increasing the orifice diameter, the gas flow rate required to maintain the gas supply pressure is increased, which results in an increase in the pressure in the processing chamber 1. When the pressure in the processing chamber 1 is increased, the process performance may deteriorate by the decrease in the energy of the gas clusters due to the collision between the gas clusters and the residual gas in the processing chamber 1. In that case, it is preferable to increase the gas cluster size by lowering the temperature of the supply gas. However, in the present embodiment, it is not necessary to lower the temperature to an extremely low temperature of 100K to 220K as in the conventional case, because the cluster gas that easily forms clusters compared to conventionally used CO₂ and that has high energy per molecule is selected based on the product Φ of the energy K per molecule or atom of the cluster generating gas and the index C indicating the ease with which the gas forms clusters. In the present embodiment, it is enough to lower the temperature to 220K or more as described above, e.g. about 220K to 373K.

<Other Applications>

While the embodiments of the present invention have been described, the present invention is not limited thereto, and various modifications may be made within the scope of the idea of the present invention. For example, in the above-described embodiment, the case in which the substrate is cleaned only by the physical action of the gas clusters has been described. However, it is also possible to ionize the gas clusters by an appropriate device and accelerate the gas clusters by electric field or magnetic field.

Description of Refernce Numeras

| 1: processing chamber | 2: substrate mounting table |
|---|---|
| 3: driving mechanism | 4: gas exhaust port |
| 5: gas exhaust line | 6: vacuum pump |
| 7: pressure control valve | |
| 10, 10′: gas cluster irradiation mechanism | |
| 11: cluster nozzle | |
| 12: cluster generating gas supply unit | |
| 20: accelerating gas supply unit | |
| 30: control unit | |
| 100, 100′: substrate cleaning apparatus | |
| C: gas cluster | S: target substrate |

What is claimed is:

1. A substrate cleaning method comprising:
supplying a cluster generating gas to a cluster nozzle at a predetermined pressure;
injecting the cluster generating gas from the cluster nozzle into a processing chamber accommodating a target substrate and maintained in a vacuum state;
generating gas clusters by adiabatically expanding the cluster generating gas; and
removing particles adhered to the target substrate by irradiating the gas clusters onto the target substrate in the processing chamber,
wherein the cluster generating gas is selected based on a product Φ of energy K per molecule or atom of the cluster generating gas injected from the cluster nozzle that is expressed by the following equation (1) and an index C indicating the ease with which the gas forms clusters that is expressed by the following equation (2),
$$K = \frac{1}{2} {mv}^{2} = \frac{γ}{γ - 1} {k}_{B} {T}_{0} \qquad ( 1 )$$
where k_{B} represents a Boltzmann constant; γ represents a specific heat ratio of the cluster generating gas; m represents a mass of the cluster generating gas; v represents a speed of the cluster generating gas; and T₀ represents a gas supply temperature,
$$C = {( \frac{{T}_{b}}{{T}_{0}} )}^{\frac{γ}{γ - 1}} \qquad ( 2 )$$
where T_{b} represents a boiling point of the cluster generating gas, T₀ represents a gas supply temperature and γ represents a specific neat ratio of the cluster generating gas.

2. The substrate cleaning method of claim 1, wherein a gas having a value of Φ greater than a value of Φ of CO₂ gas is used as the cluster generating gas.

3. The substrate cleaning method of claim 2, wherein a supply temperature of the cluster generating gas is 220K or more.

4. The substrate cleaning method of claim 3, wherein the cluster generating gas is any one of C₃H₆, C₃H₈, and C₄H₁₀.

5. The substrate cleaning method of claim 1, wherein an accelerating gas for accelerating the gas cluster is mixed with the cluster generating gas and the mixed gas is supplied to the cluster nozzle.

6. The substrate cleaning method of claim 5, wherein the accelerating gas is H₂ or He.

7. The substrate cleaning method of claim 1, wherein a size of the gas cluster is controlled by a supply pressure of the cluster generating gas or the mixed gas, a supply temperature of the cluster generating gas or the mixed gas, or an orifice diameter of the cluster nozzle.

8. A substrate cleaning apparatus for cleaning a substrate by using gas clusters, comprising:
a processing chamber accommodating a target substrate and maintained in a vacuum state;
a substrate holding unit configured to hole the target substrate in the processing chamber;
a gas exhaust unit configured to exhaust the processing chamber;
a cluster generating gas supply unit configured to supply a cluster generating gas; and
a cluster nozzle configured to inject the cluster generating gas supplied from the cluster generating gas supply unit at a predetermined pressure into the processing chamber and irradiate gas clusters generated by adiabatic expansion of the cluster generating gas onto the target substrate,
wherein the cluster gas supply unit uses as the cluster generating gas a gas selected based on a product Φ of energy K per molecule or atom of the cluster generating gas injected from the cluster nozzle that is expressed by the following equation (1) and an index C indicating the ease with which the gas forms clusters that is expressed by the following equation (2),
$$K = \frac{1}{2} {mv}^{2} = \frac{γ}{γ - 1} {k}_{B} {T}_{0} \qquad ( 1 )$$
where k_{B} represents a Boltzmann constant; γ represents a specific heat ratio of the cluster generating gas; m represents a mass of the cluster generating gas; v represents a speed of the cluster generating gas; and T₀ represents a gas supply temperature,
$$C = {( \frac{{T}_{b}}{{T}_{0}} )}^{\frac{γ}{γ - 1}} \qquad ( 2 )$$
where T_{b} represents a boiling point of the cluster generating gas, T₀ represents a gas supply temperature and γ represents a specific heat ratio of the cluster generating gas.

9. The substrate cleaning apparatus of claim 8, wherein a gas having a value of Φ greater than a value of Φ of CO₂ gas is used as the cluster generating gas.

10. The substrate cleaning apparatus of claim 9, wherein a supply temperature of the cluster generating gas is 220K or more.

11. The substrate cleaning apparatus of claim 9, wherein the cluster generating gas is any one of C₃H₆, C₃H₈, and C₄H₁₀.

12. The substrate cleaning apparatus of claim 8, further comprising an accelerating gas supply unit configured to supply an accelerating gas for accelerating the gas clusters,
wherein the acceleration gas is mixed with the cluster generating gas and the mixed gas is supplied to the cluster nozzle.

13. The substrate cleaning apparatus of claim 12, wherein the accelerating gas is H₂ or He.

14. The substrate cleaning apparatus of claim 8, wherein a size of the gas clusters is controlled by a supply pressure of the cluster generating gas or the mixed gas, a supply temperature of the cluster generating gas or the mixed gas, or an orifice diameter of the cluster nozzle.

15. A method of selecting a cluster generating gas in supplying a cluster generating gas to a cluster nozzle at a predetermined pressure, injecting the cluster generating gas from the cluster nozzle into a processing chamber accommodating a target substrate and maintained in a vacuum state, and removing particles of the target object by irradiating gas clusters generated by adiabatic expansion of the cluster generating gas onto the target substrate,
wherein the cluster generating gas is selected based on a product Φ of energy K per molecule or atom of the cluster generating gas injected from the cluster nozzle that is expressed by the following equation (1) and an index C indicating the ease with which the gas forms clusters that is expressed by the following equation (2),
$$K = \frac{1}{2} {mv}^{2} = \frac{γ}{γ - 1} {k}_{B} {T}_{0} \qquad ( 1 )$$
where k_{B} represents a Boltzmann constant; γ represents a specific heat ratio of the cluster generating gas; m represents a mass of the cluster generating gas; v represents a speed of the cluster generating gas; and T₀ represents a gas supply temperature, and
$$C = {( \frac{{T}_{b}}{{T}_{0}} )}^{\frac{γ}{γ - 1}} \qquad ( 2 )$$
where T_{b} represents a boiling point of the cluster generating gas; T₀ represents a gas supply temperature; and γ represents a specific heat ratio of the cluster generating gas.

16. The method of selecting a cluster generating gas of claim 15, wherein a gas having a value of Φ greater than Φ of CO₂ gas is selected.
